(19) United States
(12) Patent Application Publication
(10) Pub. No.: US 2016/0156156 A1
(43) Pub. Date: Jun. 2, 2016

(54) SEMICONDUCTOR INTERBAND CASCADE LASERS WITH ENHANCED OPTICAL CONFINEMENT

(71) Applicant: The Board of Regents of the University of Oklahoma, Norman, OK (US)

(72) Inventor: Rui Q. Yang, Norman, OK (US)

(21) Appl. No.: 15/012,238

(22) Filed: Feb. 1, 2016

Related U.S. Application Data
(63) Continuation-in-part of application No. 14/571,945, filed on Dec. 16, 2014, now Pat. No. 9,287,683.
Application No. 14/571,945 is a division of application No. 12/975,008, filed on Dec. 21, 2010, now Pat. No. 8,929,417.
(60) Provisional application No. 62/110,157, filed on Jan. 30, 2015.
(60) Provisional application No. 62/144,606, filed on Apr. 8, 2015.
(60) Provisional application No. 61/288,701, filed on Dec. 21, 2009.

(51) Int. Cl. H01S 5/34; H01S 5/10; H01S 5/20; H01S 5/343; H01S 5/32

(52) U.S. Cl. CPC H01S 5/3402; H01S 5/343; H01S 5/3211; H01S 5/2031; H01S 5/3216; H01S 5/1046

(57) ABSTRACT

A semiconductor interband cascade laser having an outer cladding layer formed from a material selected from the group consisting of a high-doped semiconductor material, a dielectric material and/or a metal, having an outer cladding layer refractive index and/or permittivity; an intermediate cladding layer formed from a semiconductor material having an intermediate cladding layer refractive index and/or permittivity which is greater than the outer cladding layer refractive index and/or permittivity; and a waveguide core having an active region having an active region refractive index and/or permittivity, the active region configured to generate light based on interband transitions, the light defining a lasing wavelength, wherein the intermediate cladding layer is positioned between the outer cladding layer and the waveguide core; and wherein the active region refractive index and/or permittivity is greater than the intermediate cladding layer refractive index and/or permittivity. The waveguide core may further include at least one separate confinement layer (SCL) positioned between the active region and the intermediate cladding layer.

### INCORPORATION BY REFERENCE

The present application claims the benefit of U.S. Provisional Application Ser. No. 62/110,157, filed Jan. 30, 2015. The present application also claims the benefit of U.S. Provisional Application Ser. No. 62/144,606, filed Apr. 8, 2015. The present application is also a continuation-in-part of U.S. Ser. No. 14/571,945, filed on Dec. 16, 2014, which is a divisional of U.S. Ser. No. 12/975,008, filed on Dec. 21, 2010, now U.S. Pat. No. 8,929,417, which claims benefit of U.S. Provisional Application Ser. No. 61/288,701, filed Dec. 21, 2009. Each of the above patent applications is hereby incorporated herein by reference in its entirety.

### STATEMENT REGARDING FEDERALLY SPONSORED RESEARCH OR DEVELOPMENT

This invention was made with Government support under Contract Number IIP-1346307 awarded by the National Science Foundation. The Government has certain rights in the invention.

### BACKGROUND

Semiconductor lasers have been developed with emission wavelengths (λ) ranging from near- to mid-infrared (λ>3 μm) and beyond. When the wavelength of a semiconductor laser is long, the cladding layer thickness of the waveguide structure for the laser must be made thicker. For instance, mid-infrared interband cascade (IC) lasers typically use a thick (2-3 μm) InAs/AlSb superlattice (SL) as the cladding layer to confine the optical wave in a waveguide (e.g., see Yang, “Mid-Infrared Interband Cascade Lasers Based on Type-II Heterostructures”, Microelectronics J. Vol. 30, 1043 (1999); Hill, et al, “MBE Growth Optimization of Sb-Based Interband Cascade Lasers”, J. Crystal Growth vol. 278, 167 (2005); and Vurgaftman, et al, “Mid-infrared interband cascade lasers operating at ambient temperatures”, New J. Phys. Vol. 11, 125015 (2009)). However, the use of such thick InAs/AlSb SL cladding layers in IC lasers is very demanding for growth by molecular beam epitaxy (MBE) due to the high number of required shutter movements. Furthermore, an InAs/AlSb SL layer has a very low thermal conductivity (κ˜0.03 W/cm·K) as indicated by Borca-Tasciuc, et al. in “Thermal conductivity of InAs/AlSb superlattices”, Microscale Thermophys. Eng. Vol. 5, 225 (2001), thus the thick SL cladding layers cause significant heating. However, because the SL cladding layer typically has a refractive index (˜3.37) that is only slightly smaller than the refractive index of the cascade (active) region (e.g., 3.43 to 3.47), its thickness cannot be substantially reduced, since that could lead to substantial leaking of the optical wave into the GaSb substrate (refractive index ˜3.8), resulting in undesirable optical loss. This situation becomes even worse if SL cladding layers are used in IC lasers for longer wavelengths because of the requirement of even thicker cladding layers.

It is an object of the present disclosure to provide an improved semiconductor interband cascade laser which solves these problems and has enhanced optical confinement and simultaneous reduction of optical loss, as compared to previous IC lasers.

### BRIEF DESCRIPTION OF THE DRAWINGS

So that the features of the presently disclosed inventive concepts can be understood in detail, a more particular description may be had by reference to the embodiments thereof that are illustrated in the appended drawings. Like or identical reference numerals are used to identify common or similar elements. The figures are not necessarily to scale and certain features and certain views of the figures may be shown exaggerated in scale or in schematic in the interest of clarity and conciseness. The appended drawings illustrate only certain embodiments and are therefore not to be considered limiting of the scope of the presently disclosed inventive concepts.

FIG. 1 is a schematic diagram of an exemplary semiconductor interband cascade laser constructed in accordance with the present disclosure.

FIG. 2 shows a pair of line graphs representing simulated optical modal and refractive index profiles for a laser having outer cladding layers of a high-doped semiconductor material and separate confinement layers (SCLs) made from an undoped or low-doped semiconductor material (Upper Panel), and a laser having an outer cladding layers of a high-doped semiconductor material, intermediate cladding layers constructed of, for example, superlattice, and SCLs made from an undoped or low-doped semiconductor material (Lower Panel), in accordance with the presently disclosed inventive concepts.

FIG. 3 is a schematic diagram of a more particular embodiment of an interband cascade laser constructed in accordance with the presently disclosed inventive concepts.

### DETAILED DESCRIPTION

The presently disclosed inventive concepts relate to a semiconductor interband cascade laser in which optical transitions occur between the conduction band and the valence band for photon emission. More particularly, but not by way of limitation, the presently disclosed inventive concepts include in at least one embodiment a semiconductor interband cascade laser constructed with (1) at least one outer cladding layer formed from a high-doped semiconductor material having a outer cladding layer refractive index, (2) an intermediate cladding layer formed from a semiconductor material having an intermediate cladding layer refractive index which is greater than the outer cladding layer refractive index, and (3) a waveguide core comprising an active region having an active region refractive index, wherein the active region is configured to generate light based on interband transitions, the light defining a lasing wavelength, wherein the intermediate cladding layer is positioned between the outer cladding layer and the waveguide core; and wherein the active region refractive index is greater than the intermediate cladding layer refractive index.

Before describing at least one embodiment of the presently disclosed inventive concepts in detail by way of exemplary description, drawings, experimentation, and results, it is to be understood that the inventive concepts are not limited in its application to the details of construction and the arrangement of the compositions, steps, or components set forth in the following description or illustrated in the drawings, examples, experiments, and/or results. The presently disclosed inventive concepts are capable of other embodiments or of being practiced or carried out in various ways. As such, the language used herein is intended to be given the broadest possible scope and meaning; and the embodiments are meant to be exemplary, not exhaustive. Also, it is to be understood that the phraseology and terminology employed herein is for the purpose of description and should not be regarded as limiting except where indicated as such.

Unless otherwise defined herein, scientific and technical terms used in connection with the presently disclosed inventive concepts shall have the meanings that are commonly understood by those of ordinary skill in the art. Further, unless otherwise required by context, singular terms shall include pluralities and plural terms shall include the singular. The nomenclatures utilized in connection with, and the laboratory procedures and techniques of, analytical chemistry, and semiconductor production described herein are those well-known and commonly used in the art.

All patents, patent applications, and non-patent publications referenced in any portion of this specification (in particular U.S. Provisional Application Ser. No. 62/110,157, filed Jan. 30, 2015, U.S. Ser. No. 14/571,945, filed on Dec. 16, 2014, U.S. Ser. No. 12/975,008, filed on Dec. 21, 2010, now U.S. Pat. No. 8,929,417, U.S. Provisional Application Ser. No. 61/288,701, and U.S. Provisional Application Ser. No. 62/144,606, filed Apr. 8, 2015), are each herein expressly incorporated by reference in their entirety to the same extent as if each individual patent, patent application, or non-patent publication was specifically and individually indicated to be incorporated by reference.

As utilized in accordance with the present disclosure, the following terms, unless otherwise indicated, shall be understood to have the following meanings: The use of the word “a” or “an” when used in conjunction with the term “comprising” in the claims and/or the specification may mean “one,” but it is also consistent with the meaning of “one or more,” “at least one,” and “one or more than one.” The use of the term “or” in the claims is used to mean “and/or” unless explicitly indicated to refer to alternatives only or the alternatives are mutually exclusive, although the disclosure supports a definition that refers to only alternatives and “and/or.” Throughout this application, the term “about” is used to indicate that a value includes the inherent variation or error for the device, the method being employed to determine the value, or the variation that exists among the study subjects. For example but not by way of limitation, when the term “about” is utilized, the designated value may vary by plus or minus fifteen percent, plus or minus twelve percent, or plus or minus eleven percent, or plus or minus ten percent, or plus or minus nine percent, or plus or minus eight percent, or plus or minus seven percent, or plus or minus six percent, or plus or minus five percent, or plus or minus four percent, or plus or minus three percent, or plus or minus two percent, or plus or minus one percent, or plus or minus one-half percent.

The use of the term “at least one” will be understood to include one as well as any quantity more than one, including but not limited to, 2, 3, 4, 5, 6, 7, 8, 9, 10, 11, 12, 13, 14, 15, 16, 17, 18, 19, 20, 21, 22, 23, 24, 25, 30, 35, 40, 45, 50, 55, 60, 65, 70, 75, 80, 85, 90, 95, 100, or more. The term “at least one” may extend up to 500 or 1000 or more, depending on the term to which it is attached; in addition, the quantities of 500/1000 are not to be considered limiting, as higher limits may also produce satisfactory results. In addition, the use of the term “at least one of X, Y and Z” will be understood to include X alone, Y alone, and Z alone, as well as any combination of X, Y and Z. The use of ordinal number terminology (i.e., “first”, “second”, “third”, “fourth”, etc.) is solely for the purpose of differentiating between two or more items and is not meant to imply any sequence or order or importance to one item over another or any order of addition, for example.

As used in this specification and claims, the words “comprising” (and any form of comprising, such as “comprise” and “comprises”), “having” (and any form of having, such as “have” and “has”), “including” (and any form of including, such as “includes” and “include”) or “containing” (and any form of containing, such as “contains” and “contain”) are inclusive or open-ended and do not exclude additional, unrecited elements or method steps.

The term “or combinations thereof” as used herein refers to all permutations and combinations of the listed items preceding the term. For example, “A, B, C, or combinations thereof” is intended to include at least one of: A, B, C, AB, AC, BC, or ABC, and if order is important in a particular context, also BA, CA, CB, CBA, BCA, ACB, BAC, or CAB. Continuing with this example, expressly included are combinations that contain repeats of one or more item or term, such as BB, AAA, AAB, BBC, AAABCCCC, CBBAAA, CABABB, and so forth. The skilled artisan will understand that typically there is no limit on the number of items or terms in any combination, unless otherwise apparent from the context.

As used herein, the term “substantially” means that the subsequently described event or circumstance completely occurs or that the subsequently described event or circumstance occurs to a great extent or degree. For example, the term “substantially” means that the subsequently described event or circumstance occurs at least 90% of the time, or at least 95% of the time, or at least 98% of the time. In general, the term “substantially” will be understood to allow for minor variations and/or deviations that do not result in a significant impact thereto.

As used herein, “continuous wave” (cw) means the operation of the laser occurs continuously (when electrical current injection occurs via dc current) and “pulsed mode” means electrical current injection in the laser occurs under a series of pulses of electrical current (regular or irregular).

Further, in this detailed description and the appended claims, each numerical value should be read once as modified by the term “about” (unless already expressly so modified), and then read again as not so modified unless otherwise indicated in context. Also, any range listed or described herein is intended to include, implicitly or explicitly, any number within the range, particularly all integers, and fractions thereof, including the end points, and is to be considered as having been so stated. For example, “a range from 3 to 300” is to be read as indicating each possible number, particularly integers, along the continuum between about 3 and about 300, including for example, 4, 5, 6, 7, 8, 9, 10, 11, 12, 13, 14, 15, 16, 17, 18, 19, 20, 21, 22, 23, 24, 25, 26, 27, 28, 29, and 30. Similarly, fractional amounts between any two consecutive integers are intended to be included herein, such as, but not limited to, 0.05, 0.1, 0.15, 0.2, 0.25, 0.3, 0.35, 0.4, 0.45, 0.5, 0.55, 0.6, 0.65, 0.7, 0.75, 0.8, 0.85, 0.9, and 0.95. For example, the range 3 to 4 includes, but is not limited to, 3.05, 3.1, 3.15, 3.2, 3.25, 3.3, 3.35, 3.4, 3.45, 3.5, 3.55, 3.6, 3.65, 3.7, 3.75, 3.8, 3.85, 3.9, and 3.95. Thus, even if specific data points within the range, or even no data points within the range, are explicitly identified or specifically referred to, it is to be understood that any data points within the range are to be considered to have been specified, and that the inventors possessed knowledge of the entire range and the points within the range.

The terms “relatively high-doped” or simply “high-doped” semiconductor material, as used herein, refer to a semiconductor material that has a doping concentration higher than the doping concentrations typically used in semiconductor lasers. Doping of semiconductor materials generally refers to the introduction of impurities into the crystalline structure to, for example, change the conductivity and/or permittivity of the semiconductor material, as is known in the art. As is also understood in the art, the permittivity of a medium (e.g., a semiconductor material) is a simplified term of the relative permittivity, and is a function of the square of the refractive index (in materials which have a refractive index). In one aspect, the use of high-doped semiconductor material used to form the outer cladding layers in certain embodiments of the present disclosure is to lower the refractive index/permittivity of the semiconductor material to less than the refractive index/permittivity of an active region of a waveguide core, of the laser at the lasing frequency/wavelength. In another aspect, the purpose of using high-doped semiconductor materials is to increase the plasmon frequency of carriers in the semiconductor material so that the plasmon frequency of the semiconductor material is closer to the lasing frequency/wavelength of the laser. Previously, the lasing frequency is usually much higher than the plasmon frequency. When the lasing frequency is close to the plasmon frequency, the refractive index/permittivity of the material at the lasing frequency is lowered. As such, the high-doped semiconductor material can be used as a good optical cladding layer. Exemplary values of “relatively high-doped semiconductor material” include doping concentrations which exceed 10¹⁸ cm⁻³, for example in a range rom about 10¹⁸ cm⁻³ to about 10²⁰ cm⁻³. In accordance with another aspect of the present disclosure, additional exemplary values include doping concentrations in the range from about 10¹⁸ cm⁻³ to about 10¹⁹ cm⁻³.

The presently disclosed inventive concepts, having now been generally described, will be more readily understood by reference to the following examples and embodiments, which are included merely for purposes of illustration of certain aspects and embodiments of the presently disclosed inventive concepts, and are not intended to limit the presently disclosed inventive concepts. Without further elaboration, it is believed that one skilled in the art can, using the present description, practice the presently disclosed inventive concepts to the fullest extent. The following examples and methods describe how to make and use the various aspects of the presently disclosed inventive concepts and are to be construed, as noted above, only as illustrative, and not limitations of the disclosure in any way whatsoever. Those skilled in the art will promptly recognize appropriate variations from the embodiments described herein.

In certain embodiments of plasmon waveguide IC lasers, high-doped InAs layers are used for the cladding layers. These high-doped InAs layers have high optical absorption loss. To reduce such a loss, a relatively thick (e.g. >1 □m) undoped InAs layer was inserted between the active region and each high-doped InAs cladding layer. These undoped InAs layers serve as separate confinement layers (SCLs). However, the insertion of such thick SCLs was found to reduce the optical light intensity confined in the center active region. Consequently, the attainable optical gain was reduced, resulting in a relatively high threshold current density. The embodiments presently disclosed have enhanced optical confinement and simultaneous reduction of optical loss, as described in further detail below.

The presently disclosed inventive concepts include, but are not limited to, a semiconductor interband cascade laser constructed with (1) at least one outer cladding layer formed from a high-doped semiconductor material having an outer cladding layer refractive index, (2) an intermediate cladding layer formed from a semiconductor material having an intermediate cladding layer refractive index which is greater than the outer cladding layer refractive index, and (3) a waveguide core comprising an active region having an active region refractive index, wherein the active region is configured to generate light based on interband transitions, the light defining a lasing wavelength, wherein the intermediate cladding layer is positioned between the outer cladding layer and the waveguide core; and wherein the active region refractive index is greater than the intermediate cladding layer refractive index.

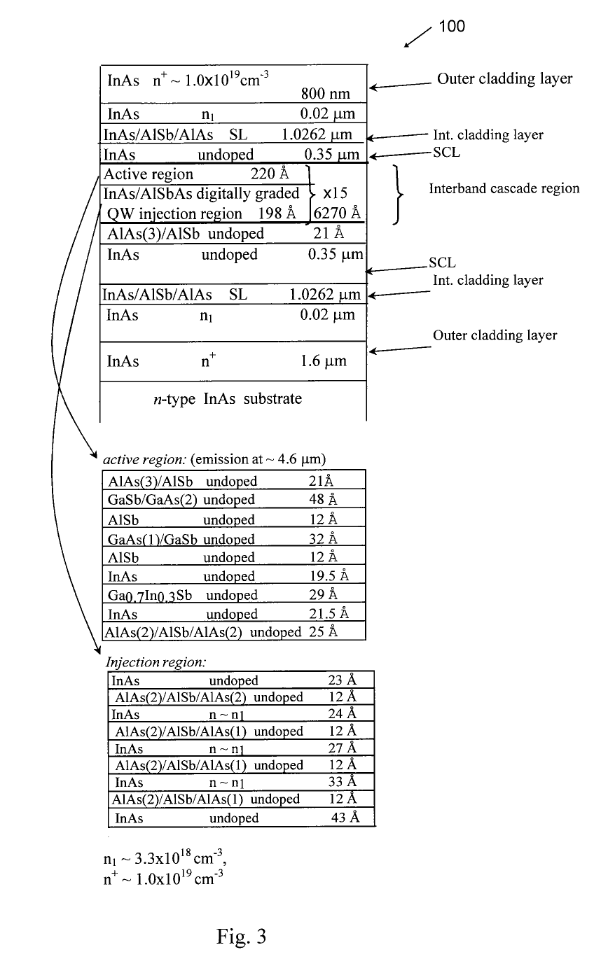

In at least certain embodiments, the intermediate cladding layer may be a superlattice layer, a ternary semiconductor material, or a quaternary semiconductor material, for example. The waveguide core may further include at least one separate confinement layer (SCL) positioned between the active region and the intermediate cladding layer, wherein the SCL is formed from a semiconductor material having a refractive index greater than the intermediate cladding layer refractive index. Associated with the difference in refractive index (or permittivity) for the cladding layer and SCL, the optical wave decays exponentially in the cladding layer, while in the SCL the wave is propagating. In at least certain embodiments, the presently disclosed waveguide interband cascade lasers differ in at least one respect from prior semiconductor lasers in that the intermediate semiconductor cladding layer is thinner, e.g., 1 μm vs 3 μm for lasers with emission wavelength range from 3 to 5 μm as shown below with reference to FIG. 3, than the thick superlattice (SL) layers (e.g. InAs/AlSb SL), or ternary (e.g. AlGaSb) material layers, or quaternary (e.g. AlGaAsSb) material layers used as cladding in the past. SL is composed of many alternating repeats of at least two thin layers of different materials. For example, InAs/AlSb SL with a period of 5 nm means that the total thickness of InAs layer and AlSb layer in one period is 5 nm. In each period, the individual layer thicknesses can be equal or nonequal. Such a SL can have many periods (e.g. 1000 periods which is 5000-nm thick). In the interband cascade lasers disclosed here, light emission is based on transitions between the conduction and valence bands, whereas in intersubband QC lasers, light emission is based on transitions between the subband states within the same band (e.g. conduction band). The level of doping in the outer cladding layer(s) will depend upon the type of semiconductor material utilized as the plasmon waveguide and can vary from the specific examples provided in this document. The outer cladding layer(s) and intermediate cladding layer(s) are used to confine the optical wave mainly in the active region, where the permittivity or refractive index in the cladding layers is smaller than that of the active region. The active region with the higher permittivity or refractive index and the cladding layers (with the lower permittivities or refractive indexes) form a waveguide structure, where the wave is mainly propagating inside the waveguide core that comprises the active region. Further description of the construction of the cladding layers is provided below.

In certain embodiments, the interband semiconductor lasers of the presently described inventive concepts are constructed with an InAs substrate, although other substrate materials can be used such as a GaSb substrate containing doped GaSb materials.

InAs has a thermal conductivity approximately 10 times higher than that of the InAs/AlSb SL. Metals that may be used for outer cladding such as Au and Ag have thermal conductivities that are about 100 times higher than the InAs/AlSb SL. Thus, replacement of thick SL cladding layers of prior lasers with doped InAs, or metal layers, significantly improves heat dissipation in the laser. Also, the growth of plasmon waveguide IC laser structures by molecular beam epitaxy (MBE) without thick SL layers is much less demanding, with dramatically reduced shutter movements as compared to the many (>1000) interfaces of the SL. Other benefits with the plasmon waveguide for IC lasers that include the intermediate cladding layer are elaborated elsewhere herein.

Another important feature is that plasmon waveguide IC lasers can achieve efficient cw operation in the longer wavelength (>6 μm) region without the difficulties associated in lasers having cladding layers comprising thick SL layers. Electroluminescence from IC light emitting diodes (without cladding layers) has been demonstrated in a 6 μm to 15 μm wavelength region. However, it is difficult for previous IC lasers with the thick SL cladding layers to cover the longer wavelength region because the optical confinement for such a long wavelength laser light requires much thicker SL cladding layers, which not only makes the growth more challenging but also leads to much worse thermal dissipation. Hence, by circumventing thick SL cladding layers, the plasmon waveguide IC lasers are capable of efficient cw operation with low power consumption in a wide range of wavelength spectrum including traditional difficult long wavelength (e.g., >6 μm) IR region for III-V interband diode lasers. Nevertheless, the SCLs in certain plasmon IC lasers, which are required to separate the high-doped semiconductor cladding layer from the active region for reducing optical absorption loss, are relatively thick (>1 μm) and thus result in the decrease of optical wave intensity in the active region. It has been discovered herein that by inserting an intermediate semiconductor cladding outside of the waveguide core, and between the outer plasmon cladding layer and the SCL, the plasmon waveguide IC lasers of the presently disclosed inventive concepts achieve significantly improved laser performance with relatively thin SCLs.

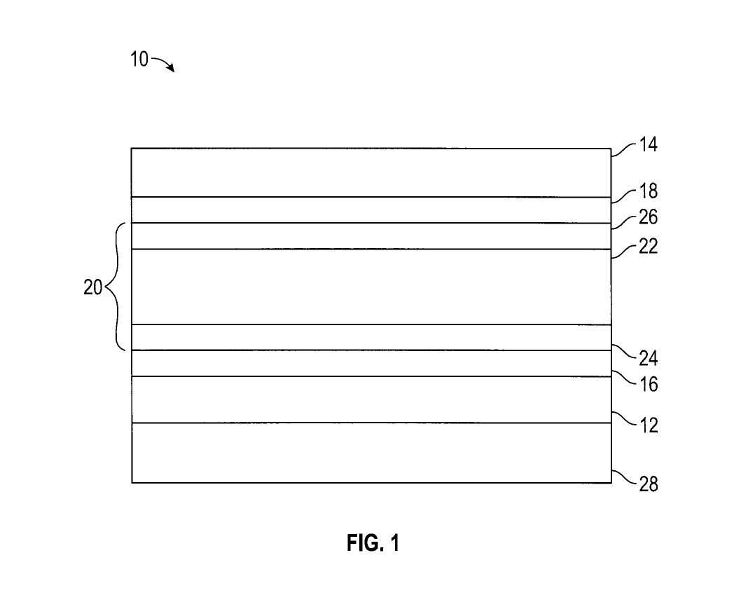

Turning now to FIG. 1, designated by reference numeral 10 is a schematic diagram of a semiconductor interband cascade laser (hereinafter referred to as “laser 10”) constructed in accordance with the presently disclosed inventive concepts. The laser 10 includes a first outer cladding layer 12, a second outer cladding layer 14, a first intermediate cladding layer 16, a second intermediate cladding layer 18, and a waveguide core 20 positioned between the first intermediate cladding layer 16 and the second intermediate cladding layer 18. The first intermediate cladding layer 16 is positioned between the first cladding layer 12 and the waveguide core 20. The second intermediate cladding layer 18 is positioned between the second cladding layer 14 and the waveguide core 20. The waveguide core 20 further includes an active region 22. The waveguide core 20 further comprises a first separate confinement layer 24 between the active region 22 and the first intermediate cladding layer 16, and a second separate confinement layer 26 between the active region 22 and the second intermediate cladding layer 18. The laser 10 can be grown on a substrate 28.

In at least one embodiment of the laser 10, the first outer cladding layer 12 is formed using a first high-doped semiconductor material having a first outer cladding refractive index (or permittivity), whereas the second outer cladding layer 14 is formed using a second high-doped semiconductor material having a second outer cladding refractive index (or permittivity). In this embodiment, the first and second high-doped semiconductor materials can be the same materials, or they can be different materials. That is, the first high-doped semiconductor material can be a different material than the second high-doped semiconductor material. The active region 22 of the waveguide core 20, also has an active region refractive index (or permittivity). The first and second outer cladding refractive indexes (or permittivities) are lower than the active region refractive index (or permittivity). For a semiconductor laser in a wavelength region of 3 μm to 5 μm based on III-V compound materials, the active region refractive index is usually in a range of from about 3.4 to about 3.5 and the high-doped semiconductor outer cladding refractive index is typically in a range of from about 3.1 to about 2.7. Where used herein, the term active region refractive index is intended to include the refractive index of the injection region of the waveguide core 20 which contains the active region 22 for the laser 10 that is an IC laser.

In certain embodiments, the first intermediate cladding layer 16 is formed using at least one of a superlattice material, a ternary semiconductor material, and a quaternary semiconductor material, the first intermediate cladding layer 16 having a first intermediate cladding refractive index (or permittivity), whereas the second intermediate cladding layer 18 is formed using at least one of a superlattice material, a ternary semiconductor material, and a quaternary semiconductor material, the second intermediate cladding layer 18 having a second intermediate cladding refractive index)(or permittivity). In this embodiment, the superlattice materials, the ternary semiconductor materials, and/or quaternary semiconductor materials of the first intermediate cladding layer 16 and the second intermediate cladding layer 18 can be the same materials, or they can be different materials. The first and second intermediate cladding refractive indexes (or permittivities) are lower than the active region refractive index (or permittivity). The first separate confinement layer (SCL) 24 has a first SCL refractive index (or permittivity) which is greater than the first intermediate cladding refractive index and the second SCL 26 has a second SCL refractive index (or permittivity) which is greater than the second intermediate cladding refractive index. In one embodiment, differences in refractive index (e.g., between the cladding layers and the SCLs) are caused by differences in compositions. For example, differences in percentage of Ga in quaternary AlGaAsSb or GaInAsSb layers result in differences in the refractive indexes. In certain non-limiting embodiments, the first SCL refractive index (or permittivity) is greater than the active region refractive index, and the second SCL refractive index (or permittivity) is greater than the active region refractive index.

In non-limiting embodiments, for a semiconductor laser in a mid-infrared wavelength region of 3-5 μm based on III-V compound materials, the outer cladding refractive index can range from about 2.7 to about 3.1, for example; the intermediate cladding refractive index can range from about 3.1 to about 3.4, for example; the SCL refractive index is typically in a range from about 3.3 to about 3.8, for example. Typically in a mid-infrared (wavelength in 3-5 μm region) III-V semiconductor laser, the thickness of a high-doped semiconductor outer cladding layer can be in a range from about 0.5 μm to about 1.5 μm, for example, the thickness of an intermediate cladding layer can be in a range from about 0.3 μm to about 1.5 μm, for example, the thickness of a SCL can be in a range from about 0.1 μm to about 1.1 μm, for example, and the thickness of an active region can be in a range from about 0.2 μm to about 1.2 μm.

The first and second outer cladding layers 12 and 14 are formed, in certain embodiments, with a high-doped semiconductor material having doping concentrations in a range of between 10¹⁸ cm⁻³ to 10¹⁹ cm⁻³. In another aspect, the doping concentrations can be in a range of between 10¹⁸ cm⁻³ to 10²⁰ cm⁻³. In another aspect, the high-doped semiconductor material used to form the first and second outer cladding layers 12 and 14 is a n⁺-type InAs with a doping concentration of at least 10¹⁸ cm⁻³.

In an alternate embodiment of the laser 10, the first outer cladding layer 12 is formed using a high-doped semiconductor material having a first permittivity, and the second outer cladding layer 14 is formed using a metal having a second permittivity. In this embodiment, the active region 22 of the waveguide core 20, has an active region permittivity. In this embodiment, the first and second permittivities of the first and second outer cladding layers 12 and 14, respectively, are lower than the active region permittivity. As discussed above, refractive index is a function of permittivity, and vice-versa. Exemplary metal which can be used to form the second outer cladding layer 14 include, but are not limited to, Ag, Au, Cu, Ti, Pt, Ni, and Pd, or combinations thereof. In metals, the plasmon frequency falls in the ultraviolet band, and the permittivity is negative. The optical confinement in the active region will be greatly enhanced in waveguides which use metal cladding in comparison to those using semiconductor material.

In an alternate embodiment of the laser 10, the first cladding layer 12 is formed using a first metal having a first permittivity, and the second cladding layer 14 is formed using a second metal having a second permittivity. The active region 22 of the waveguide core 20 has an active region permittivity. In this embodiment, the first and second permittivities of the first and second outer cladding layers 12 and 14, respectively, are lower than the active region permittivity. As discussed above, refractive index is a function of permittivity, and vice-versa. Exemplary metals used to form the first and second cladding layers 12 and 14 include, but are not limited to, Ag, Au, Cu, Ti, Pt, Ni, and Pd, or combinations thereof. The metals used to form the first and second cladding layers 12 and 14 may be the same or different.

The active region 22 of the laser 10 is adapted to generate light based on interband transitions. As would be understood in the art, the light being generated based on interband transitions thereby defines the lasing wavelength, or the lasing frequency of the laser 10. A more particular example of an active region 22 is described herein below with respect to the following figures. In one aspect, the active region 22 can comprises an interband cascade region. However, other active regions are also considered within the scope of the presently disclosed inventive concepts. In accordance with another aspect of the present disclosure, the active region 22 is adapted to generate light based on interband transitions wherein the wavelength of the light is greater than 3.0 μm, e.g., up to about 300 μm (for example from 3.0 μm up to 4.0 μm, 5.0 μm, 6.0 μm, 7.0 μm, 8.0 μm, 9.0 μm, 10.0 μm, 11.0 μm, 12.0 μm, 13.0 μm, 14.0 μm, 15.0 μm, 16.0 μm, 17.0 μm, 18.0 μm, 19.0 μm, 20.0 μm, 21.0 μm, 22.0 μm, 23.0 μm, 24.0 μm, 25.0 μm, 26.0 μm, 27.0 μm, 28.0 μm, 29.0 μm, or 30.0 μm).

As noted above, in certain embodiments, the waveguide core 20 of laser 10 further includes the first SCL 24 and the second SCL 26 positioned between the active region 22 and the first intermediate cladding layer 16, and the second intermediate cladding layer 18, respectively. Although each first SCL 24 and second SCL 26 is shown as being a single layer, it is to be understood that each first SCL 24 and second SCL 26 can be formed using a plurality of layers of materials. Exemplary materials that can be used to form each first SCL 24 and second SCL 26 include, but are not limited to, InAs, InAsSb, InGaAs, InGaAsSb, GaSb, GaInSb, AlGaSb, AlGaInSb, GaAs, AlInSb, AlSbAs, AlGaSbAs, or AlGaInSbAs, or combinations thereof. As discussed above, the materials forming the layers of the each first SCL 24 and second SCL 26 can be doped, low-doped, or not doped.

As noted above, the laser 10 can be grown on the substrate 28. The substrate 28 can be formed of, for example, InAs material having a substrate refractive index or substrate permittivity. In one aspect the refractive index or permittivity of the substrate 28 is lower than the active region refractive index or the active region permittivity. Also, as noted above, the laser 10 may be absent the substrate 28. For example, the substrate 28 can be removed after growth of the laser 10 by known techniques. For example, a metal layer can be deposited directly adjacent to the first outer cladding layer 12 to form a double-metal waveguide, in which outer cladding layer 12 can be very thin (e.g. tens to hundreds of nm) because the metal layer can be used as an additional bottom optical cladding layer.

In an alternate embodiment, the presently disclosed inventive concepts include a semiconductor interband cascade laser similar to laser 10 except constructed without the first outer cladding layer 12, such that the waveguide core 20 is positioned directly upon the substrate 28, which acts as an outer cladding layer. In another alternate embodiment, the presently disclosed inventive concepts include a semiconductor interband cascade laser similar to laser 10 except constructed without the second outer cladding layer 14 and without the second intermediate cladding layer 18. In this embodiment, a dielectric insulating layer having a low refractive index and metal layer can be deposited on the top of laser 10 to act as the outer cladding layer.

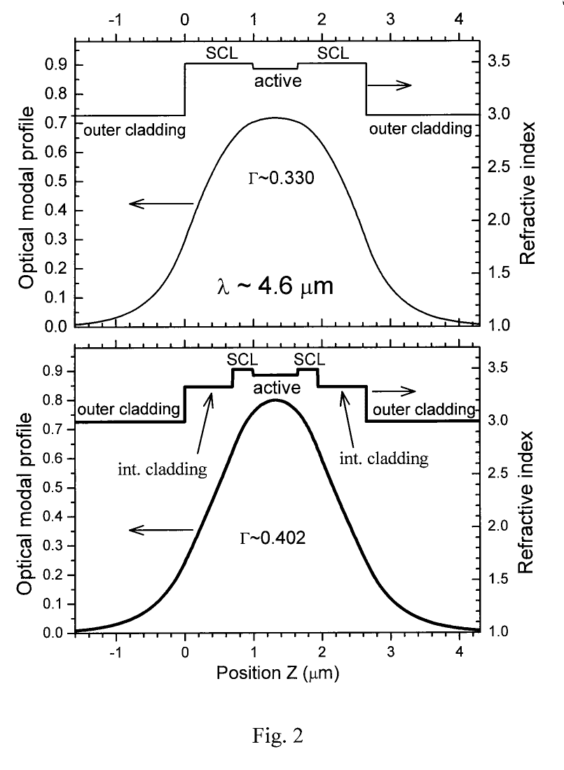

Shown in FIG. 2 is a comparison of two types of mid-IR semiconductor interband cascade lasers. The upper panel of FIG. 2 represents a semiconductor interband cascade laser having high-doped semiconductor plasmon outer cladding layers and inner separate confinement layers (SCLs) which surround an active region. The refractive index of the outer cladding layers (˜3.0) is less than the refractive index of the SCLs (˜3.5). The refractive index of the SCLs is greater than the refractive index of the active region (˜3.44). The lower panel of FIG. 2 represents a semiconductor interband cascade laser configured as in FIG. 1 having high-doped semiconductor plasmon outer cladding layers, intermediate cladding layers (for example constructed of superlattice (SL), ternary semiconductor material, or quaternary semiconductor material), and a waveguide core comprising inner SCLs surrounding an active region. The refractive index of the outer cladding layers (˜3.0) is less than the refractive index of the intermediate cladding layers (˜3.33), which is less than the refractive index of the active region (˜3.44). Further, the refractive index of the SCLs (˜3.5) is greater than the refractive index of the intermediate layers, as well as greater than the refractive index of the active region.

In lasers with thicker SCLs (FIG. 2, upper panel), a significant portion of the optical intensity profile resides in the SCL region and thus the optical confinement factor (F) in the center active region is relatively small (Γ=0.33). However, the configuration of the laser in the lower panel (wherein a portion of each SCL is substituted with the corresponding intermediate cladding layer) substantially improves the optical confinement factor (Γ=0.402). As noted, the refractive index of the semiconductor intermediate cladding layer is smaller than the refractive index of the center active region. Insertion of the semiconductor intermediate cladding layers between the outer cladding layers and the SCLs cause the optical light intensity to decay as an exponential function in the cladding layers whereas, in contrast, the optical light intensity varies as a propagating wave function in the SCLs. As a result, the optical wave is substantially more contained in the center active region with a significantly enhanced confinement factor (>40% in the example of FIG. 2). As such, the optical modal gain will be increased and the optical light intensity in the plasmon outer cladding region (Γₑ) would be reduced (by more than 20% for the example of FIG. 2). Consequently, the laser with intermediate cladding layers will have less optical loss and a lower threshold current density. Therefore, the performance of the laser represented in the lower panel of FIG. 2 will be improved over the performance of the laser represented in the upper panel of FIG. 2.

To summarize, the semiconductor interband cascade laser shown in the lower panel of FIG. 2 thus comprises a semiconductor interband cascade laser, particularly in the mid-infrared region, having plasmon outer cladding layers, intermediate semiconductor or SL cladding layers, and separate confinement layers (SCLs). In the laser having thick SCL (upper panel, FIG. 2), a significant portion of the optical field extends into the SCL region and thus the optical confinement factor (Γ) in the center active region is relatively small. To improve Γ, a regular semiconductor cladding layer with a refractive index that is smaller than the refractive index of the active region is used to replace a portion of SCL (as shown in FIG. 2, lower panel). With the insertion of this regular semiconductor cladding layer between the plasmon outer cladding and the SCLs, the optical field confinement within active region is significantly improved. As such, the optical modal gain will be enhanced and the optical field in the plasmon outer cladding region (Γₑ) should be reduced, resulting in the lower optical loss and the lower threshold current density. Therefore, the laser performance will be better.

With reference now to FIG. 3, shown therein is a schematic diagram of a specific example of an IC laser 100 having the configuration of laser 10 of FIG. 1 as constructed in accordance with the presently disclosed inventive concepts. The IC laser 100 of FIG. 3 can be grown in a molecular beam epitaxy (MBE) system on an n-type InAs substrate. In one non-limiting embodiment, the laser 100 comprises an interband cascade region having a thickness of 627 nm containing 15 alternating active regions and injection regions. Each active region and adjacent injection region forms an interband cascade stage that has a thickness of 418 Å. A cascade stage comprises many layers that are made of compound semiconductor materials as indicated in FIG. 3 with AlAs or GaAs interfaces for balancing compressive strain from AlSb and Ga(In)Sb layers for example. For the example shown in FIG. 3, the thickness of each layer is specified and is designed for lasing near ˜4.6 μm at around room temperature (˜280-300K). The interband cascade region is sandwiched by two SCL regions that are made of undoped (or, alternatively, slightly doped) InAs. In the embodiment shown in FIG. 3, the interband cascade region and the two SCL regions form the waveguide core 20 discussed above in FIG. 1 that is sandwiched by the outer cladding layers 12 and 14 and intermediate cladding layers 16 and 18. In this non-limiting embodiment, each outer cladding layer is formed from a pair of high doped n-type InAs materials that are heavily doped with Si (a primary outer cladding layer 800 nm, or 1600 nm, thick comprising n-type doped InAs with Si to 1.0×10¹⁹ cm⁻³, and an optional connecting bridge layer 20 nm thick comprising n-type doped InAs with Si to 3.3×10¹⁸ cm⁻³ for connecting to the intermediate cladding layer). In this embodiment, each intermediate cladding layer comprises InAs/AlSb/AlAs SL with a period of 4.8 nm. Given the present disclosure, such semiconductor laser devices can be manufactured by conventional processes known to persons having ordinary skill in the art. For example, an IC laser 100 shown in FIG. 3 can be processed into deep-etched 150-μm-wide mesa-stripe and narrow (about 15 μm to 20 μm-wide) ridge laser devices, both with metal contacts on the top layer and bottom substrate.

It will be understood from the foregoing description that various modifications and changes may be made in the various embodiments of the lasers of the present disclosure without departing from their true spirit. For example, the cladding layers, SCLs, substrates, and active regions and injection regions of the cascade regions of the lasers can be constructed in a variety of manners and with various materials, and thicknesses of materials and layers. The description provided herein is intended for purposes of illustration only and is not intended to be construed in a limiting sense. Thus, while the presently disclosed inventive concepts have been described herein in connection with certain embodiments so that aspects thereof may be more fully understood and appreciated, it is not intended that the presently disclosed inventive concepts be limited to these particular embodiments. On the contrary, it is intended that all alternatives, modifications and equivalents are included within the scope of the presently disclosed inventive concepts as defined herein. Thus the examples described above, which include particular embodiments, will serve to illustrate the practice of the presently disclosed inventive concepts, it being understood that the particulars shown are by way of example and for purposes of illustrative discussion of particular embodiments of the presently disclosed inventive concepts only and are presented in the cause of providing what is believed to be a useful and readily understood description of procedures as well as of the principles and conceptual aspects of the inventive concepts. Changes may be made in the formulation of the various components and compositions described herein, the methods described herein or in the steps or the sequence of steps of the methods described herein without departing from the spirit and scope of the presently disclosed inventive concepts.

What is claimed is:

1. A semiconductor interband cascade laser, comprising:
an outer cladding layer comprising a material selected from the group consisting of a high-doped semiconductor material and a metal, and having an outer cladding layer refractive index or permittivity;
an intermediate cladding layer comprising a semiconductor material having an intermediate cladding layer refractive index or permittivity which is greater than the outer cladding layer refractive index or permittivity; and
a waveguide core comprising an active region having an active region refractive index or permittivity, the active region configured to generate light based on interband transitions, the light defining a lasing wavelength, wherein the intermediate cladding layer is positioned between the outer cladding layer and the waveguide core; and
wherein the active region refractive index or permittivity is greater than the intermediate cladding layer refractive index or permittivity.

2. The semiconductor interband cascade laser of claim 1, wherein the intermediate cladding layer is selected from the group consisting of a superlattice layer, a ternary semiconductor material, and a quaternary semiconductor material, and the outer cladding layer comprises a plasmon cladding layer.

3. The semiconductor interband cascade laser of claim 1, wherein the waveguide core further includes at least one separate confinement layer (SCL) positioned between the active region and the intermediate cladding layer, said SCL comprising a semiconductor material having an SCL refractive index or permittivity greater than the intermediate cladding layer refractive index or permittivity.

4. The semiconductor interband cascade laser of claim 3, wherein the SCL refractive index or permittivity is greater than the active region refractive index or permittivity.

5. The semiconductor interband cascade laser of claim 3, wherein the semiconductor material of the SCL is selected from the group consisting of InAs, InAsSb, InGaAs, InGaAsSb, GaSb, GaInSb, AlGaSb, AlGaInSb, GaAs, AlInSb, AlSbAs, AlGaSbAs, and AlGaInSbAs.

6. The semiconductor interband cascade laser of claim 1, wherein the active region of the waveguide core comprises at least one semiconductor layer selected from a group of semiconductor materials consisting of InAs, InAsSb, InGaAs, InGaAsSb, GaSb, GaInSb, AlGaSb, AlGaInSb, GaAs, AlSb, AlAs, AlInSb, AlSbAs, AlGaSbAs, and AlInGaSbAs.

7. The semiconductor interband cascade laser of claim 1, wherein the material of the outer cladding layer is a high-doped semiconductor having a doping concentration in a range of between about 10¹⁸ cm⁻³ to about 10²⁰ cm⁻³.

8. The semiconductor interband cascade laser of claim 7, wherein the high-doped semiconductor material forming the outer cladding layer is n⁺-type InAs.

9. The semiconductor interband cascade laser of claim 1, further comprising a substrate supporting the outer cladding layer, the intermediate cladding layer and the waveguide core, the substrate being constructed of an InAs material and the outer cladding layer is adjacent to the substrate.

10. The semiconductor interband cascade laser of claim 1, further comprising a substrate supporting the outer cladding layer, the intermediate cladding layer and the waveguide core, the substrate being constructed of a n⁺-type InAs material having a substrate refractive index or permittivity lower than the active region refractive index or permittivity, the outer cladding layer, the intermediate cladding layer and the waveguide core being grown on the substrate.

11. A semiconductor interband cascade laser comprising:
a first outer cladding layer comprising a material selected from the group consisting of a high-doped semiconductor material, a dielectric material, and a metal, and having a first outer cladding layer refractive index or permittivity;
a first intermediate cladding layer comprising a semiconductor material having a first intermediate cladding layer refractive index or permittivity which is greater than the first outer cladding layer refractive index or permittivity;
a second outer cladding layer comprising a material selected from the group consisting of a high-doped semiconductor material, a dielectric material, and a metal, and having a second outer cladding refractive index or permittivity;
a second intermediate cladding layer comprising a semiconductor material having a second intermediate cladding layer refractive index or permittivity which is greater than the second outer cladding refractive index or permittivity; and
a waveguide core comprising an active region having an active region refractive index or permittivity, the active region configured to generate light based on interband transitions, the light defining a lasing wavelength at a lasing frequency, wherein the waveguide core is positioned between the first intermediate cladding layer and the second intermediate cladding layer, and wherein the first outer cladding layer is positioned external to the first intermediate cladding layer and the second outer cladding layer is positioned external to the second intermediate cladding layer; and
wherein the active region refractive index or permittivity is greater than the first intermediate cladding layer refractive index or permittivity, and is greater than the second outer cladding refractive index or permittivity.

12. The semiconductor interband cascade laser of claim 11, wherein the first intermediate cladding layer is selected from the group consisting of a superlattice layer, a ternary semiconductor material and a quaternary semiconductor layer, and the second intermediate cladding layer is selected from the group consisting of a superlattice layer, a ternary semiconductor material and a quaternary semiconductor layer.

13. The semiconductor interband cascade laser of claim 11, wherein the waveguide core further includes a first separate confinement layer (first SCL) positioned between the active region and the first intermediate cladding layer and a second separate confinement layer (second SCL) positioned between the active region and the second intermediate cladding layer, said first SCL and second SCL each comprising at least one semiconductor material, the first SCL having a first SCL permittivity greater than the first intermediate cladding layer refractive index or permittivity, and the second SCL having a second SCL refractive index or permittivity greater than the second intermediate cladding layer refractive index or permittivity.

14. The semiconductor interband cascade laser of claim 13, wherein the first SCL refractive index or permittivity is greater than the active region refractive index or permittivity, and the second SCL refractive index or permittivity is greater than the active region refractive index or permittivity.

15. The semiconductor interband cascade laser of claim 11, wherein at least one of the first outer cladding layer and the second outer cladding layer is formed from a high-doped semiconductor material doped with a doping concentration in a range of between about 10¹⁸ cm⁻³ to about 10²⁰ cm⁻³.

16. The semiconductor interband cascade laser of claim 15, wherein the high-doped semiconductor material is a n⁺-type InAs.

17. The semiconductor interband cascade laser of claim 11, wherein the first outer cladding layer and/or the second outer cladding layer are formed from at least one metal.

18. The semiconductor interband cascade laser of claim 11, further comprising a substrate supporting the first outer cladding layer, the first intermediate cladding layer, the second outer cladding layer, the second intermediate cladding layer and the waveguide core, wherein the substrate is an InAs material.

19. The semiconductor interband cascade laser of claim 18, wherein the substrate is a n⁺-type InAs material having a substrate refractive index or permittivity lower than the active region refractive index or permittivity.

20. The semiconductor interband cascade laser of claim 11, wherein the first outer cladding layer has a first plasmon frequency which is comparable to or higher than the lasing frequency; and the second outer cladding layer has a second plasmon frequency which is comparable to or higher than the lasing frequency.

21. A semiconductor interband cascade laser comprising:
a first outer cladding layer comprising a high-doped semiconductor material having a first outer cladding layer permittivity;
a first intermediate cladding layer comprising a semiconductor material having a first intermediate cladding layer refractive index or permittivity which is greater than the first outer cladding layer refractive index or permittivity;
a second outer cladding layer comprising a metal having a second outer cladding permittivity;
a second intermediate cladding layer comprising a semiconductor material having a second intermediate cladding layer refractive index or permittivity which is greater than the second outer cladding refractive index or permittivity; and
a waveguide core comprising an active region having an active region refractive index or permittivity, the active region configured to generate light based on interband transitions, the light defining a lasing wavelength at a lasing frequency, wherein the waveguide core is positioned between the first intermediate cladding layer and the second intermediate cladding layer, and wherein the first outer cladding layer is positioned external to the first intermediate cladding layer and the second outer cladding layer is positioned external to the second intermediate cladding layer; and
wherein the active region refractive index or permittivity is greater than the first intermediate cladding layer refractive index or permittivity, and is greater than the second outer cladding refractive index or permittivity.
